(19) United States
(12) Patent Application Publication
(10) Pub. No.: US 2023/0422622 A1
(43) Pub. Date: Dec. 28, 2023

(54) SELF-ADJUSTING AIRFOIL

(71) Applicant: QATAR UNIVERSITY, Doha (QA)

(72) Inventors: Asan Gani Abdul MUTHALIF, Doha (QA); Muhammad HAFIZH, Al-Khor (QA); Jamil RENNO, Doha (QA); Mohammad Roshun PAUROBALLY, Al Gharrafa (QA)

(21) Appl. No.: 18/215,110

(22) Filed: Jun. 27, 2023

Related U.S. Application Data
(60) Provisional application No. 63/355,966, filed on Jun. 27, 2022.

(51) Int. Cl. H10N 30/30; H02J 7/00; H02J 50/00

(52) U.S. Cl. CPC H10N 30/30; H02J 7/00; H02J 50/001

(57) ABSTRACT

Systems, methods, apparatuses, and computer program products for harvesting energy using a self-adjusting rotating airfoil piezoelectric energy harvester for fluid-flow applications. A method may include detecting, by an airfoil, an incoming fluid flow. The method may also include oscillating, by a bluff body of the airfoil, perpendicular to a direction of the fluid flow. The method may further include converting mechanical strain from the oscillation into electrical energy. In addition, the method may include storing the electrical energy.

### CROSS-REFERENCE TO RELATED APPLICATIONS

This application claims priority from U.S. provisional patent application No. 63/355,966 filed on Jun. 27, 2022. The contents of this earlier filed application are hereby incorporated by reference in their entirety.

### FIELD

Some example embodiments may generally relate to technologies to harvest energy. More specifically, certain example embodiments may relate to a device for harvesting energy using a self-adjusting rotating airfoil piezoelectric energy harvester for fluid-flow applications.

### BACKGROUND

With the growing innovations in Internet of Things (IoT), automated monitoring and remote sensing applications may become increasingly important in the modern world. Thus, a reliable inspection may be crucial to monitor potential risks of failure that may seriously affect the pipeline integrity and, thus, human health, safety, and the environment. The recent advances in wireless communication, high accuracy sensors, and data analysis methods have presented an emerging technology that can be widely used in pipelines monitoring applications. However, with thousands of distributed sensors and wireless communication routers, the power supply can be a challenge for a remote sensing system's efficient and sustainable operation.

With the above in mind, there is a need for a design, development, and testing of a nonlinear airfoil shaped piezoelectric energy harvester from flow-induced vibration.

### SUMMARY

Some embodiments may be directed to a method. The method may include detecting, by an airfoil, an incoming fluid flow. The method may also include oscillating, by a bluff body of the airfoil, perpendicular to a direction of the fluid flow. The method may further include converting mechanical strain from the oscillation into electrical energy. In addition, the method may include storing the electrical energy.

Other embodiments may be directed to an airfoil. The airfoil may include a rotating mechanism. The airfoil may also include a substrate airfoil beam connected to the rotating mechanism. In addition, the airfoil may include a cylindrical bluff body attached to the substrate beam. Further, the airfoil may include a composite piezoelectric harvester configured to harvest electrical energy converted from mechanical strain.

Other example embodiments may be directed to an apparatus. The apparatus may include means for detecting an incoming fluid flow. The apparatus may also include means for oscillating perpendicular to a direction of the fluid flow. The apparatus may further include means for converting mechanical strain from the oscillation into electrical energy. In addition, the apparatus may include means for storing the electrical energy.

In accordance with other example embodiments, a non-transitory computer readable medium may be encoded with instructions that may, when executed in hardware, perform a method. The method may include detecting an incoming fluid flow. The method may also include oscillating perpendicular to a direction of the fluid flow. The method may further include converting mechanical strain from the oscillation into electrical energy. In addition, the method may include storing the electrical energy.

Other example embodiments may be directed to a computer program product that performs a method. The method may include detecting an incoming fluid flow. The method may also include oscillating perpendicular to a direction of the fluid flow. The method may further include converting mechanical strain from the oscillation into electrical energy. In addition, the method may include storing the electrical energy.

Other example embodiments may be directed to an apparatus that may include circuitry configured to detect an incoming fluid flow. The apparatus may also include circuitry configured to oscillate perpendicular to a direction of the fluid flow. The apparatus may further include circuitry configured to convert mechanical strain from the oscillation into electrical energy. In addition, the apparatus may include circuitry configured to store the electrical energy.

### BRIEF DESCRIPTION OF THE DRAWINGS

The accompanying drawings, which are included to provide a further understanding of the invention and are incorporated in and constitute a part of this specification, illustrate preferred embodiments of the invention and together with the detail description serve to explain the principles of the invention. In the drawings:

FIG. 1 illustrates an example airfoil, according to certain embodiments.

FIG. 2 illustrates a perspective view of the airfoil in FIG. 1, according to certain embodiments.

FIG. 3 illustrates another example airfoil, according to certain embodiments.

FIG. 4 illustrates an example enhanced view of the airfoil, according to certain embodiments.

FIG. 5 illustrates example geometric parameters for the airfoil, according to certain embodiments.

FIG. 6 illustrates example material properties of a piezoelectric macrofibre composite, according to certain embodiments.

FIG. 7 illustrates an example trailing vortex formation behind the bluff body, according to certain embodiments.

FIG. 8 illustrates an example passive self-aligning rotation axis airfoil beam, according to certain embodiments.

FIG. 9 illustrates an example piezoelectric composite optimal strain positioning, according to certain embodiments.

FIG. 10 illustrates an example mode shapes of an airfoil-based energy harvester, according to certain embodiments.

FIG. 11 illustrates an example flow diagram of a method, according to certain example embodiments.

FIG. 12 illustrates an apparatus according to certain example embodiments.

### DETAILED DESCRIPTION

It will be readily understood that the components of certain example embodiments, as generally described and illustrated in the figures herein, may be arranged and designed in a wide variety of different configurations. The following is a detailed description of some embodiments of systems, methods, apparatuses, and/or computer program products for harvesting energy using a self-adjusting rotating airfoil piezoelectric energy harvester for fluid-flow applications.

The features, structures, or characteristics of example embodiments described throughout this specification may be combined in any suitable manner in one or more example embodiments. For example, the usage of the phrases “certain embodiments,” “an example embodiment,” “some embodiments,” or other similar language, throughout this specification refers to the fact that a particular feature, structure, or characteristic described in connection with an embodiment may be included in at least one embodiment. Thus, appearances of the phrases “in certain embodiments,” “an example embodiment,” “in some embodiments,” “in other embodiments,” or other similar language, throughout this specification do not necessarily all refer to the same group of embodiments, and the described features, structures, or characteristics may be combined in any suitable manner in one or more example embodiments.

Additionally, if desired, the different functions or steps discussed below may be performed in a different order and/or concurrently with each other. Furthermore, if desired, one or more of the described functions or steps may be optional or may be combined. As such, the following description should be considered as merely illustrative of the principles and teachings of certain example embodiments, and not in limitation thereof.

Certain embodiments may provide a design, development, and testing of a nonlinear airfoil shaped piezoelectric energy harvester from flow-induced vibration. According to certain embodiments, the harvester may be used to convert flow-induced vibration from active transport fluids into electrical energy that can be conveniently stored and used to power smart remote sensors. For instance, in some embodiments, the harvested electrical energy may be stored in a capacitor or battery. In other embodiments, an energy harvesting module may be integrated or a standalone system may be fabricated to store the harvested electrical energy. Other embodiments may provide a passive self-adjustable mechanism (i.e., self-aligning mechanism) that can compensate for the changing flow direction and conditions that can reduce the conversion efficiency of energy harvesters.

As a result of the inherent nonlinear behavior of the cantilevered piezoelectric composite, the design process may possess a challenge prospect for optimization studies with misalignment flow that may reduce the efficiency of conventional piezoelectric energy harvesters. The use of advanced modeling and simulation techniques may reduce the time-to-market if suitably used. Additionally, although current practices in fluid-flow application of energy harvesting are well-explored in research, practical applications for use in pipeline industries or integration with wireless sensor nodes for remote sensing applications with self-aligning ability are still challenges that need to be addressed. Furthermore, conventional methods do not have a self-aligning mechanism since laboratory testing usually focuses on one velocity and direction only. Thus, in certain embodiments, the airfoil can resolve these challenges by being able to adjust to the changes in the environment and flow conditions. Certain embodiments may also introduce nonlinearity by unrestricting the airfoil alignment that generates nonlinear resonance to the structure in different mode shapes.

Certain embodiments may address the narrowband linear frequency response of conventional vibration energy harvesters. The self-aligning mechanism in certain embodiments compensates for turbulence and flow direction changes that can negatively affect the energy conversion efficiency. Thus, certain embodiments may address a nonlinear broadband approach to increasing fluid-flow applications of energy harvesting using piezoelectric composites. For instance, according to certain embodiments, a method of energy harvesting from a direct flow-source can address the shortcomings of using batteries to deploy wireless sensor nodes across an array of pipeline systems.

Certain embodiments may provide a self-aligned/self-feathering mechanism for airline and helicopter industry for airfoil tuning. Additionally, other embodiments may provide a passive mobile device charging module that can convert kinetic energy from movement and walking to be used to charge devices. In energy harvesting applications, the desired flow conditions may be outside of the bandwidth limitations. For each pipeline construction, the known conditions of flow and medium properties may be known. Thus, certain embodiments, may design around the flow conditions within a certain lower and upper limit to maximize conversion efficiency.

According to certain embodiments this bandwidth limitation may be solved by having another adjustable mechanism to shift the bandwidth limitation by shifting the natural frequency of the energy harvesting material (i.e., adjusting the boundary condition of the airfoil harvester). According to other embodiments, for oil, natural gas, chemical processes or water applications, the entire structure may be designed to ensure that the material does not breakdown from the active transport of the fluids. According to other embodiments, this may be addressed by careful inspection of the fluid transport in the pipe and selecting the most appropriate materials that does not actively break-down and does not seep and contaminate the fluid transport.

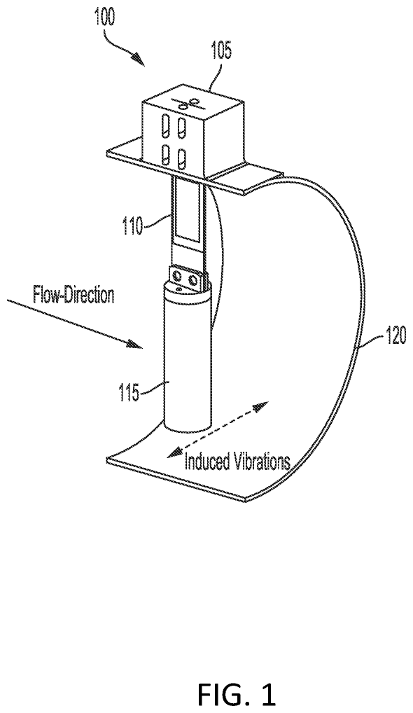

FIG. 1 illustrates an example airfoil 100, according to certain embodiments. Some embodiments may provide a device that improves on the existing product to harvest energy from fluid-flow for remote sensing applications. For instance, in certain embodiments, an airfoil 100 may be provided and placed inside a pipe 120 (cross-section of pipe 120 illustrated in FIG. 1). The airfoil 100 may be used to power wireless sensor nodes from the incoming flow by a piezoelectric composite attached to the beam that converts kinetic energy to electrical energy. In certain embodiments, the wireless sensor nodes (not illustrated) may be an integrated package of sensors and transmitters that are embedded on the pipe 120 or are used for other diagnostic purpose(s). The airfoil 100 may harvest the energy which may be used to power the wireless sensor nodes. For instance, as illustrated in FIG. 1, the airfoil 100 may convert flow-induced vibration from active transport fluids into electrical energy via the piezoelectric patch on an airfoil-shaped composite layered beam 110. The electrical energy may then be stored and used to power smart remote sensors. As illustrated in FIG. 1, the airfoil 100 may include an electronic box 105, and the electronic box 105 may include a converter, a 4G transmission device, and storage for power and data. The airfoil 100 may also include an airfoil-shaped composite layered beam 110 that oscillates from incoming fluid flow when attached to the bluff body 115. The macrofibre composite piezoelectric patch 125 attached to the beam 110 may convert mechanical strain into electrical energy that can be harvested. The airfoil 100 may also include a bluff body 115, which forms vortices due to layer separation, and leads to transverse oscillations.

According to certain embodiments, the airfoil 100 can harvest energy from fluid-flow by way of the bluff body 115 and a piezoelectric harvester 125 of the airfoil-shaped composite layered beam 110. The bluff body 115 may be a bluff body that forms vorticity due to flow separation. Due to the pressure differences, the bluff body 115 may oscillate perpendicular to the direction of flow. The airfoil 100 may be attached to the bluff body 115 and move perpendicularly due to the coupled system. The piezoelectric harvester 125 converts the mechanical strain from the movement while being attached to the airfoil 100 in the form of an electric charge.

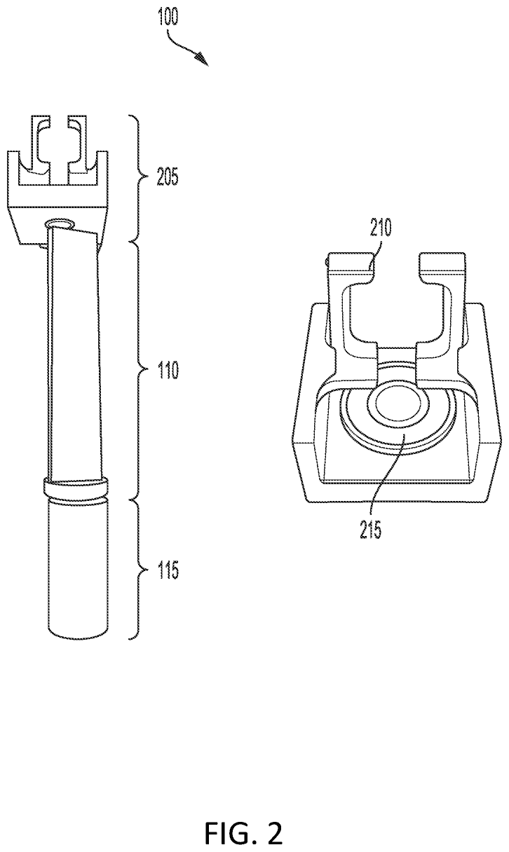

To compensate for the changes in flow direction and conditions, certain embodiments may utilize a self-aligning mechanism which uses an airfoil-based geometry and a rotational mount 205 at the top (achieved with a bearing) of the airfoil 100 that can be locked or unlocked as illustrated in FIG. 2. As illustrated in FIG. 2, the harvester assembly (110 and 115) is connected to the rotating mechanism 205. The cylindrical extension at 110 is fitted inside hole/bearing mount 215, and allows for free rotation. The geometry of the airfoil-shaped composite layered beam 110, when subjected to incoming flow, may self-align due to the pressure difference. The airfoil-based geometry may correspond to a profile shape or envelope that defines the curvature of the upper and lower surfaces of the airfoil 100. For instance, in some embodiments, the airfoil 100 may be symmetrical, which allows for the self-aligning property. In other embodiments, the rotational mount 205 may hold the rotational bearing 215 and may be fitted into an opening slot of the pipe 120, as illustrated in the electronic box 105. The rotational mount 205 may serve to connect both the pipe 110 and the rotating harvester assembly (110 and 115).

As illustrated in FIG. 2, the rotational mount 205 may include a clamping mount 210 that attaches to the pipeline, and a bearing mount 215 that enables free-rotation of the airfoil-shaped composite 110. In certain embodiments, the clamping mount 210 may attach to the pipeline by press-fitting the clamping mount 210 inside a pipe opening. The fixture may then be screwed on both sides to achieve clamping. According to certain embodiments, the self-aligning mechanism (not shown) may be an extension of the airfoil 100 which extends and fits inside the rotational mount 205. Additionally, the self-aligning mechanism may utilize the free rotation of the bearing mount 215. In other embodiments, the airfoil may be able to adjust to the changes in the environment and flow conditions. This may be accomplished, for example, by self-aligning towards the direction of the highest flow when there is an incoming flow stream coming into contact with the airfoil-shaped composite layered beam 110.

According to certain embodiments, the self-alignment mechanism for rotation may be performed by other ways than a bearing. For example, the self-alignment mechanism for rotation may be performed by a gear-pinion, electromagnetic-torque, and/or variable resistor. For instance, in embodiments, for the gear-pinion, the bearing mount 215 may be replaced with a central gear with inwards teeth, and the airfoil-shaped composite 110 may have a press-fit pinion which may be mounted to the bearing mount 215. In other embodiments, the electromagnetic-torque may supply energy that can force the rotation, or a torque brake may be used to limit the orientation. The variable resister may limit the rotation ability, but may not be feasible to use. In some embodiments, the design of the beam that may not be limited to using the same designation of airfoil design (i.e., non-standard shapes, different National Advisory Committee for Aeronautics (NACA) models.

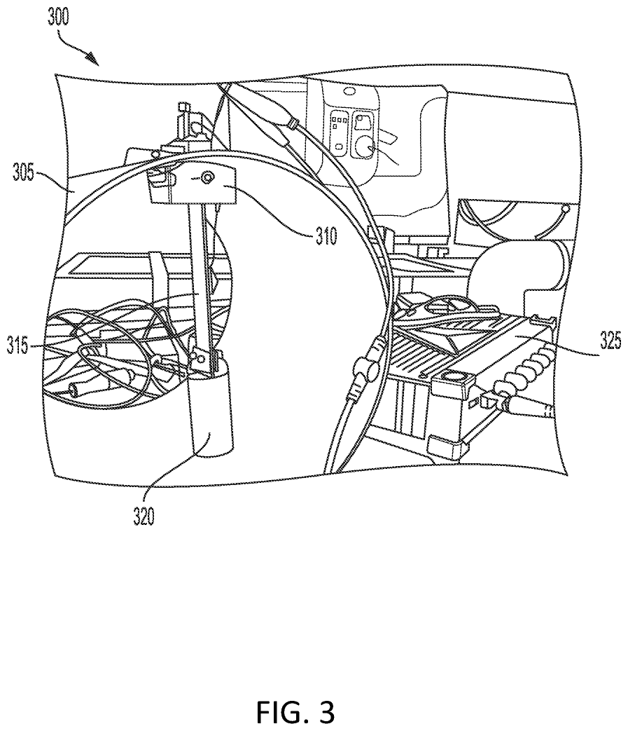

FIG. 3 illustrates another example airfoil 300, according to certain embodiments. As illustrated in FIG. 3, the airfoil 300 may correspond to the airfoil 100 illustrated in FIGS. 1 and 2. In particular, certain embodiments may have a minimum variable product-type (MVP-type) design where, as illustrated in FIG. 3, the airfoil 300 may be fitted inside a pipe array 305, and data (e.g., raw voltage output, which can be analyzed in various forms) may be collected through a data acquisition system 325. As illustrated in FIG. 3, similar to the airfoil 100 illustrated in FIGS. 1 and 2, the airfoil 300 may include a rotational mechanism 310 attached to an airfoil-shaped piezoelectric composite layered beam 315 via a bearing mount allowing for free-rotation of the rotational mechanism 310. The rotational mechanism 310 may also be attached to the pipe array 305, and the airfoil-shaped piezoelectric composite layered beam 315 may be attached/mounted on a bluff body 320. Further, adjustment restrictions may be adjusted using the rotational mechanism 310.

According to certain embodiments, for the energy harvester with a cylindrical body and substate beam placed underwater, vortices may form behind the bluff body 115 such that periodic oscillations occur in the direction perpendicular to the flow of water. These oscillations may be modeled as a mass-spring-damper system expressed per unit time as Eq. 1:

(M+Mₐ)\ddot{x}+(C+Cₐ+Cₚ)\dot{x}+(K+Kₐ+Kₚ)x+ΘVₚ=F(t) Eq. 1.

Where M is the equivalent mass, C is the equivalent damping, and K is the equivalent stiffness. \ddot{x}, \dot{x}, and x represent the acceleration, velocity, and displacement of the oscillations, respectively. The subscript ‘a’ denotes the added-mass hydrodynamic effect of submerged bodies. The effect with the electromechanical piezoelectric patch is modeled with Θ as the electromechanical coupling coefficient and Vₚ is the voltage produced. The current that is generated from the piezoelectric macrofibre composite with term I, can be represented by Eq. 2 where C s is the clamped capacitance value:

I(t)=Θ\dot{x}(t)−C⁵\dot{V}(t) Eq. 2.

When the energy harvester (e.g., airfoil 100) is submerged in water and oscillates due to the vortices, the transverse force FT may be modeled as a forced vibration system using a two-parameter self-excitation model with in-phase and out-of-phase forces in Eq. 3:

$$\\ \begin{matrix}{F}_{T} = \frac{ρ {U}^{2} DL ( {C}_{mv} sin ( 2 π ft ) + {C}_{dv} cos ( 2 π ft ) )}{2} . & Eq . 3\end{matrix}$$

Here, p represents the density of the flowing fluid, U is the freestream flow velocity, D is the diameter of the bluff body, and L is the wetted span of the cylinder. Cₘᵥ represents the oscillating inertia coefficient while C_{dv} represents the oscillating negative damping coefficient. The cylinder oscillating frequency is represented by f. Synchronization occurs for frequencies where the vortex shedding frequency is equal to the harvester's natural frequency. Frequency-matching of both frequencies may be achieved for different velocities by using the Strouhal number where U is the freestream velocity of incoming flow:

$$\\ \begin{matrix}St = \frac{fD}{U} . & Eq . 4\end{matrix}$$

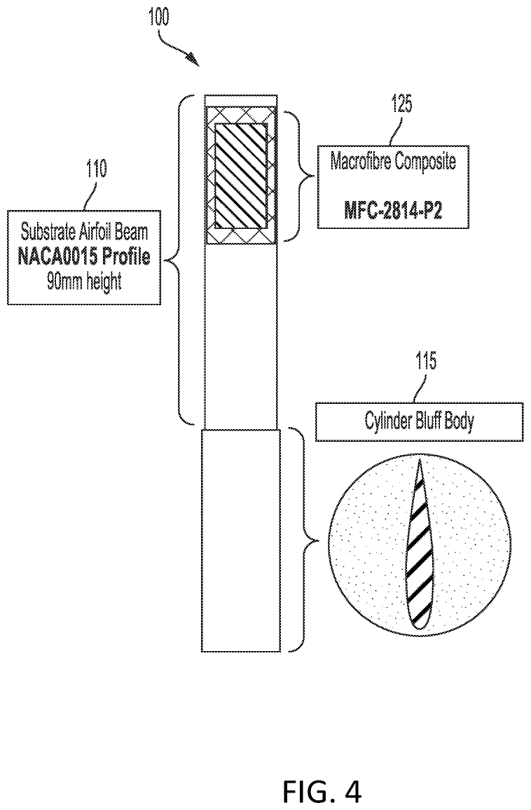

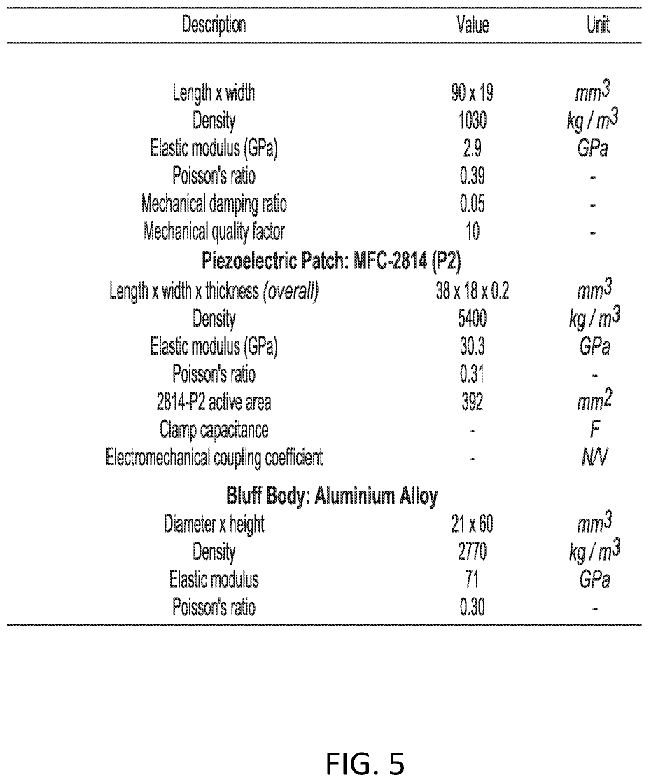

FIG. 4 illustrates an enhanced view of the example airfoil piezoelectric energy harvester 100, according to certain embodiments. As illustrated in FIG. 4, the airfoil 100 may include the cylinder bluff body 115, and the airfoil-shaped composite layered beam 110 at a height of about 90 mm. The airfoil-shaped piezoelectric composite layered beam may include a macrofibre composite piezoelectric harvester 125. The geometric parameters for the airfoil 100 are illustrated in FIG. 5.

According to certain embodiments, a validation of the analytical model and analysis of the energy harvesting performance may be performed on a computational simulation. For instance, software may be used to analyze the viscous and inertial forces of the fluid interaction from the flow-induced vibration. In certain embodiments, the computational setup may be performed with second order spatial discretization and implicit transient formulation settings. The computation domain may be performed with a distance 10D upstream from the bluff body, 30D downstream, and 20D total width, with D being the diameter of the bluff body. This domain may be sufficiently large enough to avoid disturbances in the flow and effects of the boundary conditions, especially when less than 5% blockage ratio is considered in the flow-field. After defining the property of the water in the domain, an inlet velocity may be defined at 0.53 m/s where the vortex shedding frequency matches the transverse mode shape of the energy harvesting system.

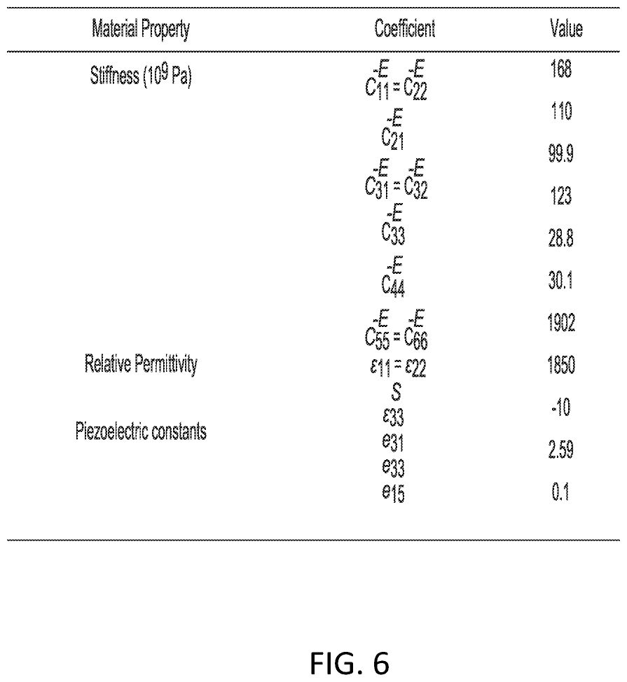

In certain embodiments, the average static reference pressure at the outlet boundary may be set at 0 Pa and a no slip boundary may be applied to the top and bottom wall of the boundary wall. A k−ω SST turbulence model may be used to solve the inner region of the boundary layer. The flow simulation may be solved suing a SIMPLE algorithm and a 2^{nd} order k−ω transport equations. The distance between the cylinder wall and the first node, y⁺ may be kept below unity with inflated mesh around the object to ensure that there is adequate resolution of grids near the cylinder in simulation, and may be maintained throughout all simulations. A time stamp of 0.002 s with 15 iterations per time step over 20 seconds may be implemented to adequately show the vortex shedding. Once completed, the force coefficients may be saved and exported to a finite element analysis model with the same timestep and vectors. The structural response may be modeled as forced response inputs with generally good accuracy. The values for voltage and displacement may be recorded with good convergence, and the constitutive equation of piezoelectric materials may be expressed in stress-charge form as Eq. 5:

$$\\ \begin{matrix}\{ \begin{matrix}\{ T \} \\ \{ D \}\end{matrix} \} = [ \begin{matrix}[ {c}^{E} ] & [ e ] \\ {[ e ]}^{T} & - [ {ε}^{S} ]\end{matrix} ] \{ \begin{matrix}\{ S \} \\ \{ E \}\end{matrix} \} . & Eq . 5\end{matrix}$$

Where {T} represents the stress, {D} represents the electric flux density, [c^{E}] represents elasticity at a constant electric field, [e] represents piezoelectric stress, [ε^{S}] is the dielectric matrix at a constant mechanical strain, {S} is the elastic strain vector, and {E} is the electric field intensity vector. The material properties of the piezoelectric macrofibre composite and the electromechanical constants that are used to convert the mechanical strain to electrical energy (charge) are shown in FIG. 6.

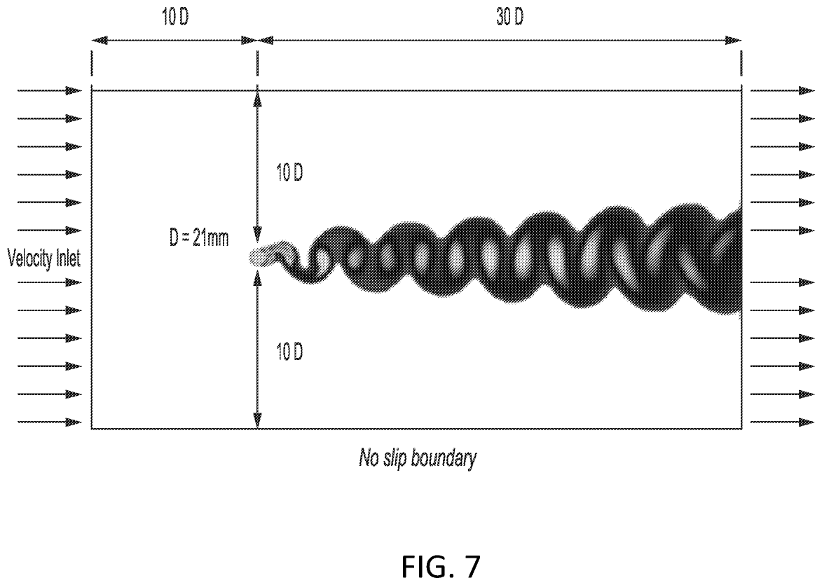

According to certain embodiments, water layer separation that forms over a bluff body forms vortices that are the driving mechanism behind the transverse oscillations in vortex-induced vibration. The amplitudes under synchronization have been demonstrated to be sufficiently high enough to harvest vibration energy from. FIG. 7 illustrates an example trailing vortex formation behind the bluff body, according to certain embodiments. In particular, FIG. 7 illustrates the trailing edge vortex shedding around the bluff body that oscillates at the frequency outlined by the Strouhal Number equation. The size and mass of the bluff body dictates the onset velocity and range for synchronization that would be a useful parameter for optimizing energy harvesters. According to some embodiments, the energy harvesting performance may either be tuned for frequency-matching at a given input, or may be adjusted to accommodate a wider range of frequencies through hybrid systems or nonlinear magnetic coupling. The trailing vortices formation may also affect the synchronization properties in the form of single (S), paired (P), or a combination of the two.

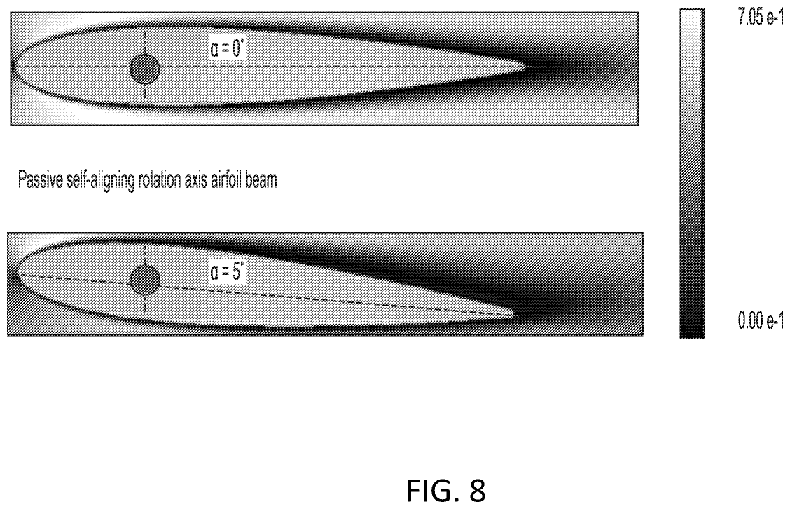

In certain embodiments, a computational simulation may be performed to observe the behavior of the airfoil to ensure that the mechanism can generate the appropriate rotating moment required for self-aligning behavior. Since the selection of the NACA0015 profile is symmetric, no lift or drag force is observed for zero angle of attack. However, deviation to a different angle of attack (a) may present changes in the velocity and pressure around the airfoil. For instance, FIG. 8 illustrates an example passive self-aligning rotation axis airfoil beam, according to certain embodiments. In particular, FIG. 8 illustrates a comparison of the velocity stream effect due to the airfoil shaped composite beam 110 where pressure differences can lead to the self-aligning property. The placement of the rotation axis in unsteady velocity fields have demonstrated self-correcting moment for finite angles of attack to allow self-alignment. The performance of the self-aligning mechanism may be dependent on the airfoil profile and thickness, which may also vary the flow separation and wake effects.

According to certain embodiments, macrofibre composites that attach to substrates may rely on correct placement along the beam to ensure that the optimal energy harvesting conversion efficiency is reached. In a traditional rectangular beam, the placement may be near the fixed end where strain is at a maximum. However, an airfoil geometry adds another layer of optimization as the curvature of the substrate may dictate the performance output of piezoelectric energy harvester (PEH).

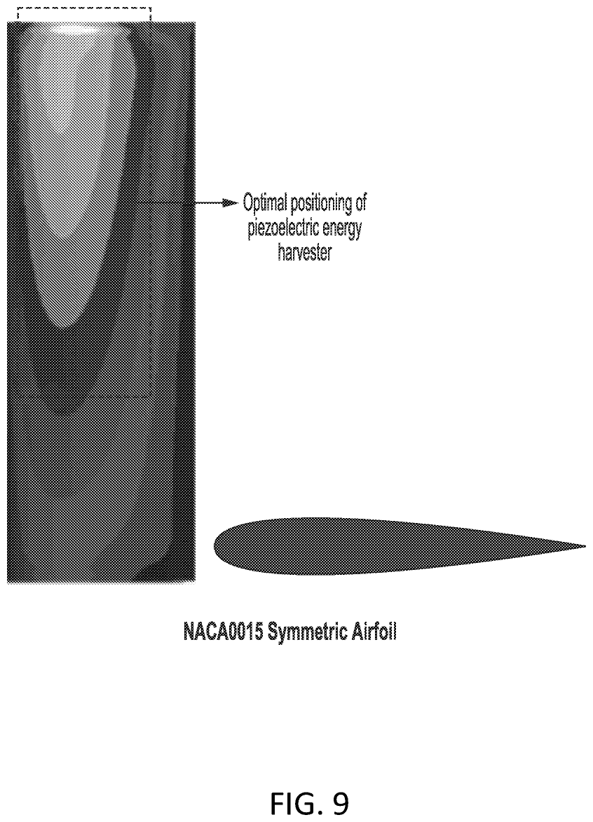

FIG. 9 illustrates an example piezoelectric composite optimal strain positioning, according to certain embodiments. In particular, FIG. 9 illustrates the strain measurements of a NACA0015 airfoil subjected to vortex-induced vibration (VIV), and illustrates a strain simulation for perpendicular deformation of bluff body motion (e.g., from VIV), and where the optimal placement of the piezoelectric energy harvester 125 can be placed to maximize charge accumulation. The position of the MFC attachment may be near the front end of the airfoil. Furthermore, the geometrical change of the beam may suggest that the thicker areas which do not deform as much experience more strain.

In certain embodiments, vibration energy harvesting may present a unique application in flow-induced energy harvesting mechanisms compared to other traditional turbine-based systems. This may be due to its lack of moving parts flexibility in miniaturization and scaling without significant losses from electromechanical properties. Additionally, VIV harvesting may take advantage of the two frequencies that oscillates the bluff body because of the lift coefficient and drag coefficient of incoming water flow. The lift may be responsible for the larger transverse oscillations and may be the mechanism behind VIV-based energy harvesters. However, the inline frequency that can be harvested in low-velocity applications presents an additional optimization parameter that can further increase the performance output.

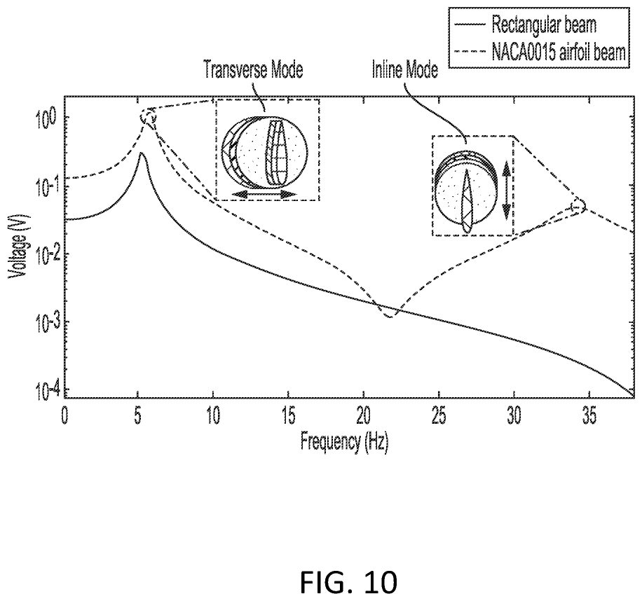

FIG. 10 illustrates an example mode shapes of an airfoil-based energy harvester, according to certain embodiments. In particular, FIG. 10 illustrates the frequency response for both a conventional rectangular beam and the energy harvester of certain embodiments with a NACA0015 airfoil beam. The voltage output from the airfoil shape 110 is higher due to larger strain concentration in the shape. Additionally, two-mode peaks are visible within a frequency range that allows for better performance optimization when targeting two frequencies (instead of only 1 limited to the rectangular beam). According to certain embodiments, the airfoil may utilize a passive self-aligning mechanism demonstrated to increase the maximum output by 290% compared to conventional rectangular beams. Additionally, the geometric shape ensures that both harvestable frequencies may be utilized at a lower velocity in comparison to a rectangular shape.

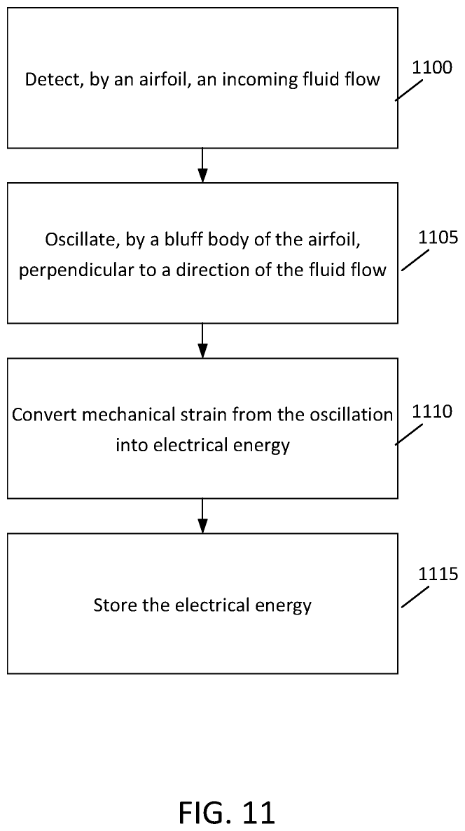

FIG. 11 illustrates an example flow diagram of a method, according to certain example embodiments. In an example embodiment, the method of FIG. 11 may be performed by an airfoil similar to the airfoil illustrated in FIGS. 1 and 2.

According to certain example embodiments, the method of FIG. 11 may include, at 1100, detecting, by an airfoil, an incoming fluid flow. The method may also include, at 1105, oscillating, by a bluff body of the airfoil, perpendicular to a direction of the fluid flow. The method may further include, at 1110, converting mechanical strain from the oscillation into electrical energy. In addition, the method may include, at 1115, storing the electrical energy.

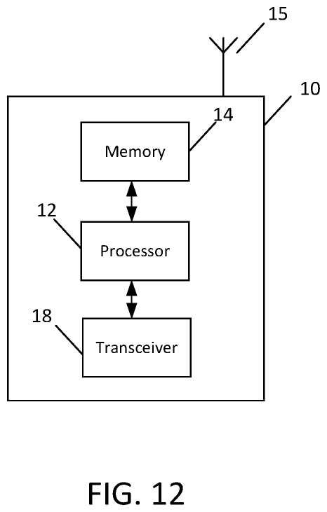

FIG. 12 illustrates an apparatus 10 according to certain example embodiments. In certain example embodiments, apparatus 10 may be an airfoil, a computer, mobile computing device, network device, server, or other similar device. In some embodiments, apparatus 10 may be in communication (i.e., connected to either via wire or wirelessly) with other similar computer devices forming a network of connected computer devices.

In some example embodiments, apparatus 10 may include one or more processors, one or more computer-readable storage medium (for example, memory, storage, or the like), one or more radio access components (for example, a modem, a transceiver, or the like), and/or a user interface.

As illustrated in the example of FIG. 12 apparatus 10 may include or be coupled to a processor 12 for processing information and executing instructions or operations. Processor 12 may be any type of general or specific purpose processor. In fact, processor 12 may include one or more of general-purpose computers, special purpose computers, microprocessors, digital signal processors (DSPs), field-programmable gate arrays (FPGAs), application-specific integrated circuits (ASICs), and processors based on a multi-core processor architecture, as examples. While a single processor 12 is shown in FIG. 12, multiple processors may be utilized according to other example embodiments. For example, it should be understood that, in certain example embodiments, apparatus 10 may include two or more processors that may form a multiprocessor system (e.g., in this case processor 12 may represent a multiprocessor) that may support multiprocessing. According to certain example embodiments, the multiprocessor system may be tightly coupled or loosely coupled (e.g., to form a computer cluster).

Processor 12 may perform functions associated with the operation of apparatus 10 including, as some examples, precoding of antenna gain/phase parameters, encoding and decoding of individual bits forming a communication message, formatting of information, and overall control of the apparatus 10, including processes illustrated in FIGS. 1-11.

Apparatus 10 may further include or be coupled to a memory 14 (internal or external), which may be coupled to processor 12, for storing information and instructions that may be executed by processor 12. Memory 14 may be one or more memories and of any type suitable to the local application environment, and may be implemented using any suitable volatile or nonvolatile data storage technology such as a semiconductor-based memory device, a magnetic memory device and system, an optical memory device and system, fixed memory, and/or removable memory. For example, memory 14 can be comprised of any combination of random access memory (RANI), read only memory (ROM), static storage such as a magnetic or optical disk, hard disk drive (HDD), or any other type of non-transitory machine or computer readable media. The instructions stored in memory 14 may include program instructions or computer program code that, when executed by processor 12, enable the apparatus 10 to perform tasks as described herein.

In certain example embodiments, apparatus 10 may further include or be coupled to (internal or external) a drive or port that is configured to accept and read an external computer readable storage medium, such as an optical disc, USB drive, flash drive, or any other storage medium. For example, the external computer readable storage medium may store a computer program or software for execution by processor 12 and/or apparatus 10 to perform any of the methods illustrated in FIGS. 1-11.

In some example embodiments, apparatus 10 may also include or be coupled to one or more antennas 15 for receiving a downlink signal and for transmitting via an uplink from apparatus 10. Apparatus 10 may further include a transceiver 18 configured to transmit and receive information. The transceiver 18 may also include a radio interface (e.g., a modem) coupled to the antenna 15. The radio interface may include other components, such as filters, converters signal shaping components, and the like, to process symbols, carried by a downlink or an uplink.

For instance, transceiver 18 may be configured to modulate information on to a carrier waveform for transmission by the antenna(s) 15 and demodulate information received via the antenna(s) 15 for further processing by other elements of apparatus 10. In other example embodiments, transceiver 18 may be capable of transmitting and receiving signals or data directly. Additionally or alternatively, in some example embodiments, apparatus 10 may include an input and/or output device (I/O device). In certain example embodiments, apparatus 10 may further include a user interface, such as a graphical user interface or touchscreen.

In certain example embodiments, memory 14 stores software modules that provide functionality when executed by processor 12. The modules may include, for example, an operating system that provides operating system functionality for apparatus 10. The memory may also store one or more functional modules, such as an application or program, to provide additional functionality for apparatus 10. The components of apparatus 10 may be implemented in hardware, or as any suitable combination of hardware and software.

According to certain example embodiments, processor 12 and memory 14 may be included in or may form a part of processing circuitry or control circuitry. In addition, in some example embodiments, transceiver 18 may be included in or may form a part of transceiving circuitry.

As used herein, the term “circuitry” may refer to hardware-only circuitry implementations (e.g., analog and/or digital circuitry), combinations of hardware circuits and software, combinations of analog and/or digital hardware circuits with software/firmware, any portions of hardware processor(s) with software (including digital signal processors) that work together to cause an apparatus (e.g., apparatus 10) to perform various functions, and/or hardware circuit(s) and/or processor(s), or portions thereof, that use software for operation but where the software may not be present when it is not needed for operation. As a further example, as used herein, the term “circuitry” may also cover an implementation of a hardware circuit or processor (or multiple processors), or portion of a hardware circuit or processor, and its accompanying software and/or firmware.

In certain example embodiments, apparatus 10 may be controlled by memory 14 and processor 12 to detect an incoming fluid flow. Apparatus 10 may also be controlled by memory 14 and processor 12 to oscillate perpendicular to a direction of the fluid flow. Apparatus 10 may further be controlled by memory 14 and processor 12 to convert mechanical strain from the oscillation into electrical energy. In addition, apparatus 10 may be controlled by memory 14 and processor 12 to store the electrical energy.

In some example embodiments, an apparatus (e.g., apparatus 10) may include means for performing a method, a process, or any of the variants discussed herein. Examples of the means may include one or more processors, memory, controllers, transmitters, receivers, sensors, and/or computer program code for causing the performance of the operations.

Certain example embodiments may further be directed to an apparatus that includes means for performing any of the methods described herein including, for example, means for detecting an incoming fluid flow. The apparatus may also include means for oscillating perpendicular to a direction of the fluid flow. The apparatus may further include means for converting mechanical strain from the oscillation into electrical energy. In addition, the apparatus may include means for storing the electrical energy.

Certain example embodiments described herein provide several technical improvements, enhancements, and/or advantages. In some example embodiments, it may be possible to provide a passively self-aligned airfoil energy harvester that can harvest water flow in low-velocity applications, and can adjust for variations in flow conditions. It may also be possible to provide an airfoil that can increase peak performance by up to 290% in comparison to a conventional rectangular beam with the same volume. Furthermore, it is possible to utilize synchronization frequencies to harvest the transverse and inline frequencies.

According to other embodiments, it may be possible to provide a self-aligning mechanism that provides excellent properties for applications in open water channels that can be used to power remote sensing applications. Certain embodiments may also ensure that VIV oscillations are perpendicular. Thus, the adoption of vibration energy harvester from fluid flow can present beneficial opportunities within the energy harvesting field that can be readily scaled and designed for different use cases. For instance, the harvesting mechanisms of certain embodiments may be used to power monitoring and diagnostic systems for pipe flow applications.

As described herein, a computer program product may include one or more computer-executable components which, when the program is run, are configured to carry out some example embodiments. The one or more computer-executable components may be at least one software code or portions of it. Modifications and configurations required for implementing functionality of certain example embodiments may be performed as routine(s), which may be implemented as added or updated software routine(s). Software routine(s) may be downloaded into the apparatus.

As an example, software or a computer program code or portions of code may be in a source code form, object code form, or in some intermediate form, and may be stored in some sort of carrier, distribution medium, or computer readable medium, which may be any entity or device capable of carrying the program. Such carriers may include a record medium, computer memory, read-only memory, photoelectrical and/or electrical carrier signal, telecommunications signal, and software distribution package, for example. Depending on the processing power needed, the computer program may be executed in a single electronic digital computer or it may be distributed amongst a number of computers. The computer readable medium or computer readable storage medium may be a non-transitory medium.

In other example embodiments, the functionality may be performed by hardware or circuitry included in an apparatus (e.g., apparatus 10), for example through the use of an application specific integrated circuit (ASIC), a programmable gate array (PGA), a field programmable gate array (FPGA), or any other combination of hardware and software. In yet another example embodiment, the functionality may be implemented as a signal, a non-tangible means that can be carried by an electromagnetic signal downloaded from the Internet or other network.

According to certain example embodiments, an apparatus, such as a node, device, or a corresponding component, may be configured as circuitry, a computer or a microprocessor, such as single-chip computer element, or as a chipset, including at least a memory for providing storage capacity used for arithmetic operation and an operation processor for executing the arithmetic operation.

One having ordinary skill in the art will readily understand that the invention as discussed above may be practiced with steps in a different order, and/or with hardware elements in configurations which are different than those which are disclosed. Therefore, although the invention has been described based upon these example embodiments, it would be apparent to those of skill in the art that certain modifications, variations, and alternative constructions would be apparent, while remaining within the spirit and scope of example embodiments.

We claim:

1. A method for harvesting energy, comprising:
detecting, by an airfoil, an incoming fluid flow;
oscillating, by a bluff body of the airfoil, perpendicular to a direction of the fluid flow;
converting mechanical strain from the oscillation into electrical energy; and
storing the electrical energy.

2. The method according to claim 1, wherein the conversion of the mechanical strain into electrical energy is performed via a piezoelectric patch on an airfoil-shaped composite layered beam of the airfoil.

3. The method according to claim 1, further comprising:
forming vorticity due to flow separation of the fluid flow.

4. The method, according to claim 1, further comprising:
compensating for a changing of flow direction of the fluid flow, and for changing of the fluid flow.

5. The method according to claim 2, wherein the electrical energy is harvested from the fluid flow by way of the bluff body and a piezoelectric harvester of the airfoil-shaped composite layered beam.

6. The method according to claim 1, further comprising:
utilizing a self-aligning mechanism to compensate for the changes in flow direction and conditions due to a pressure difference.

7. The method according to claim 6, wherein utilizing the self-aligning mechanism comprises utilizing an airfoil-based geometry and a rotational mount of the airfoil.

8. The method according to claim 6, wherein the self-aligning mechanism utilizes a free rotation of a bearing mount to self-align towards a direction of s highest flow when there is an incoming flow stream.

9. An airfoil, comprising:
a rotating mechanism;
a substrate airfoil beam connected to the rotating mechanism;
a cylinder bluff body attached to the substrate airfoil beam; and
a composite piezoelectric harvester configured to harvest electrical energy converted from mechanical strain.

10. The airfoil according to claim 9, wherein the rotating mechanism comprises a bearing mount that allows for free rotation of the substrate airfoil beam and the cylinder bluff body.

11. The airfoil according to claim 9, wherein the rotating mechanism comprises a clamping mount that is attached to a pipeline via press-fitting the clamping mount inside the pipeline.

12. The airfoil according to claim 9, further comprising:
an electronic box,
wherein the electronic box comprises a converter, a radio transmission device, and storage for power and data.

13. The airfoil according to claim 9, wherein the airfoil is symmetrical.

14. The airfoil according to claim 9,
wherein the rotational mount comprises a rotational bearing, and
wherein the rotational mount is fitted into an opening slot of a pipe housing the airfoil.

15. A computer program embodied on a non-transitory computer readable medium, the computer program comprising computer executable code which, when executed by a processor, causes the processor to:
detect an incoming fluid flow;
oscillate perpendicular to a direction of the fluid flow;
converting mechanical strain from the oscillation into electrical energy; and
storing the electrical energy.

16. The computer program according to claim 15, wherein the conversion of the mechanical strain into electrical energy is performed via a piezoelectric patch on an airfoil-shaped composite layered beam of the apparatus.

17. The method according to claim 15, wherein the computer program comprises the computer executable code which, when executed by the processor, further causes the processor to:
form vorticity due to flow separation of the fluid flow.

18. The method, according to claim 15, wherein the computer program comprises the computer executable code which, when executed by the processor, further causes the processor to:
compensate for a changing of flow direction of the fluid flow, and for changing of the fluid flow.

19. The method according to claim 16, wherein the electrical energy is harvested from the fluid flow by way of a bluff body and a piezoelectric harvester of the airfoil-shaped composite layered beam.

20. The method according to claim 15, wherein the computer program comprises the computer executable code which, when executed by the processor, further causes the processor to:
utilize a self-aligning mechanism to compensate for the changes in flow direction and conditions due to a pressure difference.
